(19) United States
(12) Patent Application Publication
(10) Pub. No.: US 2024/0339360 A1
(43) Pub. Date: Oct. 10, 2024

(54) MICROFEATURE WORKPIECES AND METHODS FOR FORMING INTERCONNECTS IN MICROFEATURE WORKPIECES

(71) Applicant: Micron Technology, Inc., Boise, ID (US)

(72) Inventors: William M. Hiatt, Eagle, ID (US); Ross S. Dando, Nampa, ID (US)

(21) Appl. No.: 18/744,493

(22) Filed: Jun. 14, 2024

Related U.S. Application Data
(63) Continuation of application No. 18/047,049, filed on Oct. 17, 2022, now Pat. No. 12,014,958.
Application No. 18/047,049 is a continuation of application No. 16/991,965, filed on Aug. 12, 2020, now Pat. No. 11,476,160.
Application No. 16/991,965 is a continuation of application No. 15/662,204, filed on Jul. 27, 2017, now abandoned.
Application No. 15/662,204 is a division of application No. 12/965,301, filed on Dec. 10, 2010, now abandoned.
Application No. 12/965,301 is a division of application No. 11/217,169, filed on Sep. 1, 2005, now Pat. No. 7,863,187.

(51) Int. Cl. H01L 21/768; H01L 23/48; H01L 23/498; H01L 23/538

(52) U.S. Cl. CPC H01L 21/76898; H01L 23/481; H01L 23/49827; H01L 23/5384; H01L 2224/13025

(57) ABSTRACT

Methods for forming interconnects in microfeature workpieces, and microfeature workpieces having such interconnects are disclosed herein. The microfeature workpieces may have a terminal and a substrate with a first side carrying the terminal and a second side opposite the first side. In one embodiment, a method includes (a) constructing an electrically conductive interconnect extending from the terminal to at least an intermediate depth in the substrate with the interconnect electrically connected to the terminal, and (b) removing material from the second side of the substrate so that a portion of the interconnect projects from the substrate.

### CROSS-REFERENCE TO RELATED APPLICATIONS

This application is a continuation of U.S. application Ser. No. 18/047,049, filed Oct. 17, 2022, which is a continuation of U.S. application Ser. No. 16/991,965 filed Aug. 12, 2020, now U.S. Pat. No. 11,476,160, which is a continuation of U.S. application Ser. No. 15/662,204 filed Jul. 27, 2017, which is a divisional of U.S. application Ser. No. 12/965,301 filed Dec. 10, 2010, which is a divisional of U.S. application Ser. No. 11/217,169 filed Sep. 1, 2005, now U.S. Pat. No. 7,863,187, each of which is incorporated herein by reference in its entirety.

### TECHNICAL FIELD

The present invention relates to methods for forming interconnects in microfeature workpieces and microfeature workpieces formed using such methods.

### BACKGROUND

Microelectronic devices, micromechanical devices, and other devices with microfeatures are typically formed by constructing several layers of components on a workpiece. In the case of microelectronic devices, a plurality of dies are fabricated on a single workpiece, and each die generally includes an integrated circuit and a plurality of bond-pads coupled to the integrated circuit. The dies are separated from each other and packaged to form individual microelectronic devices that can be attached to modules or installed in other products.

One aspect of fabricating and packaging such dies is forming interconnects that electrically couple conductive components located in different layers. In some applications, it may be desirable to form interconnects that extend completely through the dies or through a significant portion of the dies. Such interconnects electrically couple bond-pads or other conductive elements proximate to one side of the dies to conductive elements proximate to the other side of the dies. Through-wafer interconnects, for example, are constructed by forming deep vias on the front side and/or backside of the workpiece and in alignment with corresponding bond-pads at the front side of the workpiece. The vias are often blind vias in that they are closed at one end. The blind vias are then filled with a conductive fill material. After further processing, the workpiece is thinned to reduce the thickness of the final dies. Solder balls or other external electrical contacts are subsequently attached to the through-wafer interconnects at the backside and/or the front side of the workpiece. The solder balls or external contacts can be attached either before or after singulating the dies from the workpiece.

Conventional processes for forming external contacts on through-wafer interconnects include (a) depositing a dielectric layer on the backside of the workpiece, (b) forming a photoresist on the dielectric layer, (c) patterning and developing the photoresist, (d) etching the dielectric layer to form holes aligned with corresponding interconnects, (e) removing the photoresist from the workpiece, and (f) forming conductive external contacts in the holes in the dielectric layer. One concern with forming external contacts on the backside of a workpiece is that conventional processes are relatively expensive because patterning the photoresist requires a mask. Masks are expensive and time-consuming to construct because they require very expensive photolithography equipment to achieve the tolerances required in semiconductor devices. Accordingly, there is a need to reduce the cost of forming external contacts on workpieces with through-wafer interconnects.

### BRIEF DESCRIPTION OF THE DRAWINGS

FIGS. 1A-1I illustrate stages of a method for forming interconnects in a microfeature workpiece in accordance with one embodiment of the invention.

FIG. 1A is a schematic side cross-sectional view of a portion of the workpiece at an intermediate stage after partially forming a plurality of interconnects.

FIG. 1B is a schematic side cross-sectional view of the area 1B shown in FIG. 1A with the workpiece flipped over.

FIG. 1C is a schematic side cross-sectional view of the portion of the workpiece after thinning the substrate from the second side.

FIG. 1D is a schematic side cross-sectional view of the portion of the workpiece after selectively removing additional material from the second side of the substrate so that the interconnect projects from the substrate.

FIG. 1E is a schematic side cross-sectional view of the area 1E shown in FIG. 1D after forming a recess in the second end portion of the interconnect.

FIG. 1F is a schematic side cross-sectional view of the portion of the workpiece after forming a dielectric structure across the second side of the substrate and the second end portion of the interconnect.

FIG. 1G is a schematic side cross-sectional view of the portion of the workpiece after removing sections of the interconnect and the dielectric structure.

FIG. 1H is a schematic side cross-sectional view of the portion of the workpiece after removing the section of the first dielectric layer from the recess in the interconnect.

FIG. 1I is a schematic side cross-sectional view of the portion of the workpiece after forming a conductive member at the second end portion of the interconnect.

FIGS. 2A-2C illustrate stages in a method for forming interconnects in a microfeature workpiece in accordance with another embodiment of the invention.

FIG. 2A is a schematic side cross-sectional view of a portion of the workpiece at an intermediate stage after partially forming an interconnect.

FIG. 2B is a schematic side cross-sectional view of the portion of the workpiece after removing sections of the interconnect and the dielectric structure.

FIG. 2C is a schematic side cross-sectional view of the portion of the workpiece after forming the conductive member on the exposed surface of the interconnect.

FIGS. 3A-3C illustrate stages in a method for forming interconnects in a microfeature workpiece in accordance with another embodiment of the invention.

FIG. 3A is a schematic side cross-sectional view of a portion of the workpiece at an intermediate stage after partially forming an interconnect.

FIG. 3B is a schematic side cross-sectional view of the portion of the workpiece after removing sections of the interconnect and the dielectric structure.

FIG. 3C is a schematic side cross-sectional view of the workpiece after forming a conductive member on the exposed surface of the interconnect.

### DETAILED DESCRIPTION

### A. Overview

The following disclosure describes several embodiments of methods for forming interconnects in microfeature workpieces, and microfeature workpieces having such interconnects. One aspect of the invention is directed to methods of forming an interconnect in a microfeature workpiece having a terminal and a substrate with a first side carrying the terminal and a second side opposite the first side. An embodiment of one such method includes (a) constructing an electrically conductive interconnect extending from the terminal to at least an intermediate depth in the substrate, and (b) removing material from the second side of the substrate so that a portion of the interconnect projects from the substrate. The material can be removed from the second side of the substrate by thinning the substrate so that a surface of the interconnect is exposed and selectively etching the substrate so that the portion of the interconnect projects from the substrate.

In another embodiment, a method includes providing a microfeature workpiece having (a) a substrate with a first side and a second side opposite the first side, (b) a terminal carried by the first side of the substrate, and (c) an electrically conductive interconnect extending from the terminal through the substrate and projecting from the second side of the substrate. The method further includes applying a dielectric layer to the second side of the substrate and the portion of the interconnect projecting from the second side of the substrate, and removing a section of the dielectric layer to expose a surface of the interconnect with the interconnect intersecting a plane defined by the remaining section of the dielectric layer.

In another embodiment, a method includes forming an electrically conductive interconnect having a first portion at the terminal and a second portion at an intermediate depth in the substrate. The electrically conductive interconnect is electrically connected to the terminal. The method further includes thinning the substrate from the second side to at least the second portion of the interconnect, applying a dielectric layer to the second side of the substrate and the second portion of the interconnect, and exposing a surface of the second portion of the interconnect without photolithography.

Another aspect of the invention is directed to microfeature workpieces. In one embodiment, a microfeature workpiece includes a substrate and a microelectronic die formed in and/or on the substrate. The substrate has a first side and a second side opposite the first side. The die includes a terminal at the first side of the substrate and an integrated circuit operably coupled to the terminal. The workpiece further includes an electrically conductive interconnect extending from the terminal through the substrate such that a portion of the interconnect projects from the second side of the substrate. The interconnect is electrically coupled to the terminal.

In another embodiment, a microfeature workpiece includes a substrate and a microelectronic die formed in and/or on the substrate. The substrate has a first side and a second side opposite the first side. The die includes a terminal at the first side of the substrate and an integrated circuit operably coupled to the terminal. The workpiece further includes (a) a hole extending through the terminal and the substrate, (b) a dielectric layer on the second side of the substrate defining a plane, and (c) an electrically conductive interconnect. The interconnect includes a conductive fill material in the hole and a conductive layer in the hole between the conductive fill material and the substrate. Both the conductive fill material and the conductive layer are electrically coupled to the terminal and extend from the terminal through the substrate. Moreover, both the conductive fill material and the conductive layer project from the substrate such that the conductive fill material and the conductive layer intersect the plane.

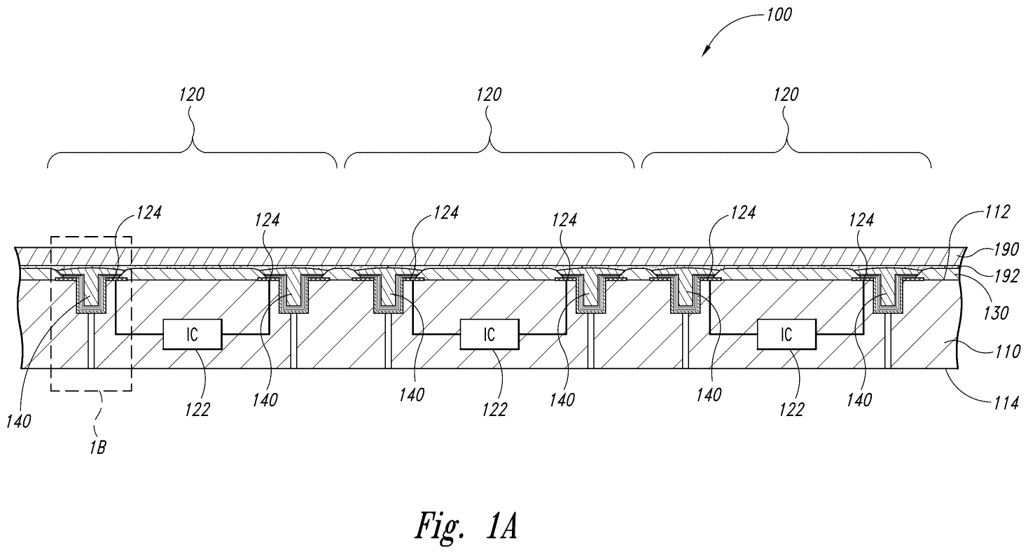

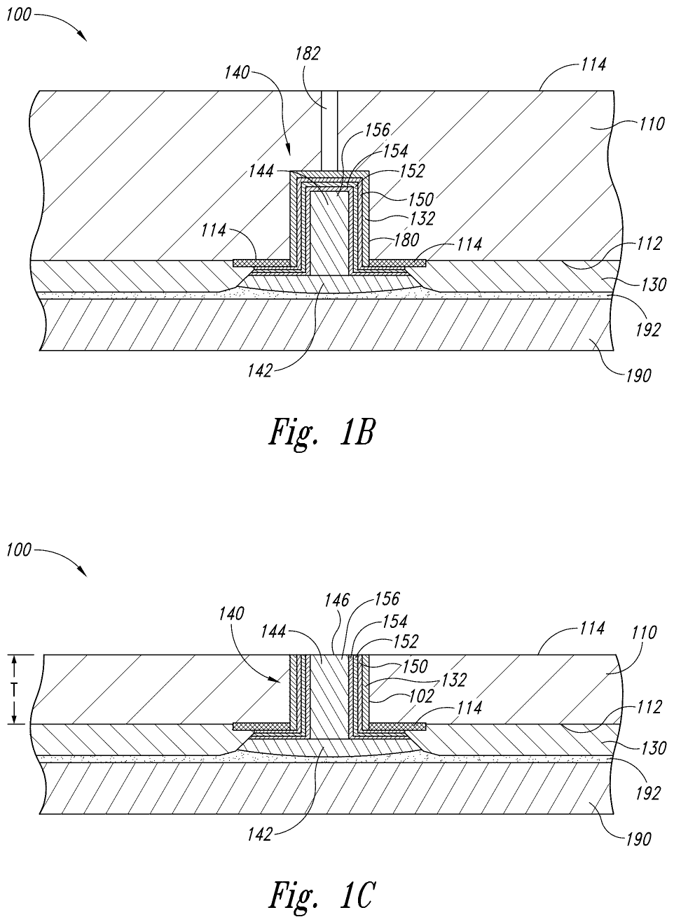

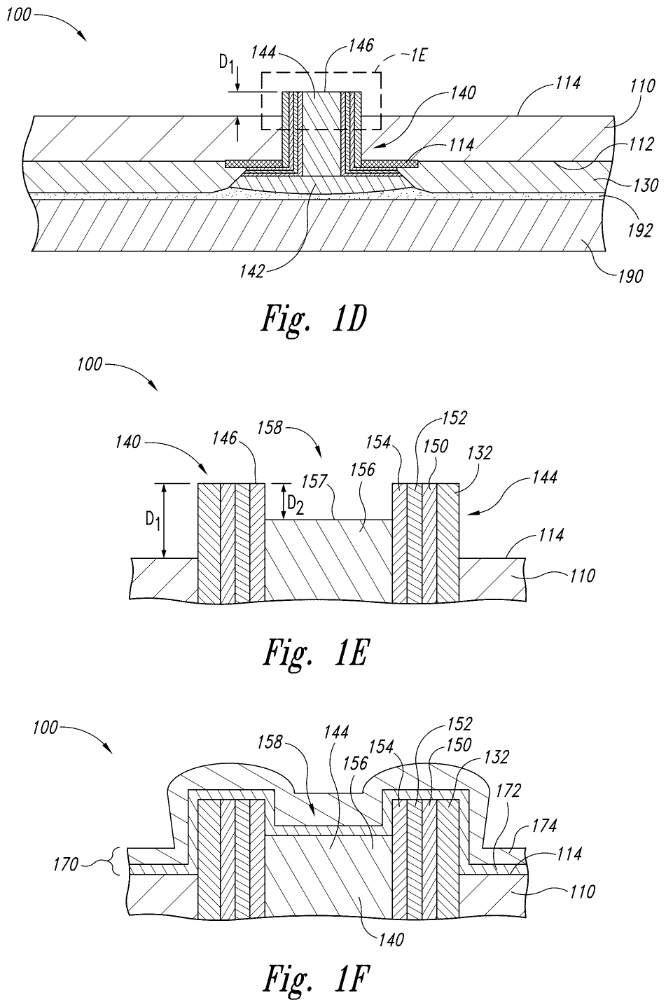

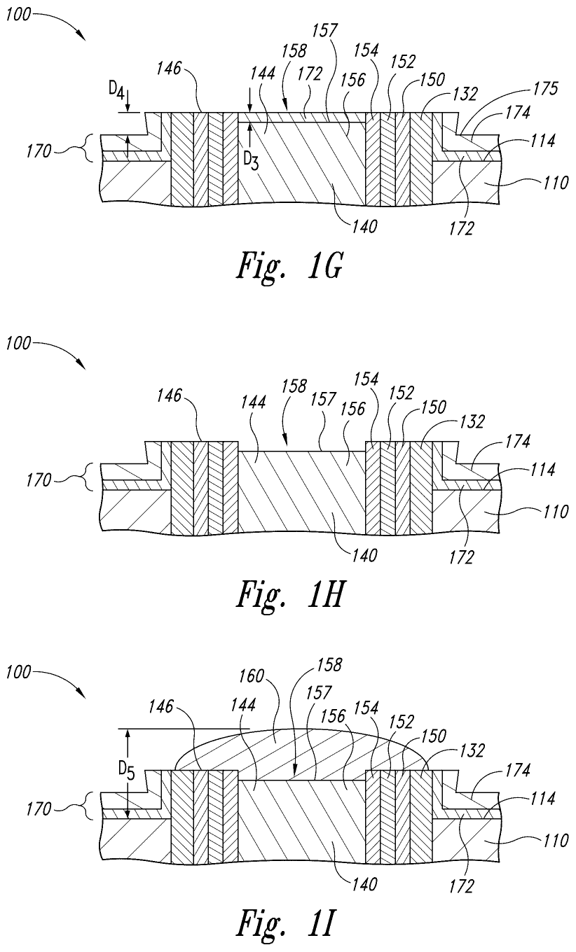

Specific details of several embodiments of the invention are described below with reference to interconnects extending from a terminal proximate to the front side of a workpiece, but the methods and interconnects described below can be used for other types of interconnects within microelectronic workpieces. Several details describing well-known structures or processes often associated with fabricating microelectronic devices are not set forth in the following description for purposes of clarity. Also, several other embodiments of the invention can have different configurations, components, or procedures than those described in this section. A person of ordinary skill in the art, therefore, will accordingly understand that the invention may have other embodiments with additional elements, or the invention may have other embodiments without several of the elements shown and described below with reference to FIGS. 1A-3C.

The term “microfeature workpiece” is used throughout to include substrates upon which and/or in which microelectronic devices, micromechanical devices, data storage elements, optics, and other features are fabricated. For example, microfeature workpieces can be semiconductor wafers, glass substrates, dielectric substrates, or many other types of substrates. Many features on such microfeature workpieces have critical dimensions less than or equal to 1 μm, and in many applications the critical dimensions of the smaller features are less than 0.25 μm or even less than 0.1 μm. Where the context permits, singular or plural terms may also include the plural or singular term, respectively. Moreover, unless the word “or” is expressly limited to mean only a single item exclusive from other items in reference to a list of at least two items, then the use of “or” in such a list is to be interpreted as including (a) any single item in the list, (b) all of the items in the list, or (c) any combination of the items in the list. Additionally, the term “comprising” is used throughout to mean including at least the recited feature(s) such that any greater number of the same features and/or types of other features and components are not precluded.

### B. Embodiments of Methods for Forming Interconnects in Microfeature Workpieces

FIGS. 1A-1I illustrate stages of a method for forming interconnects in a microfeature workpiece 100 in accordance with one embodiment of the invention. FIG. 1A, for example, is a schematic side cross-sectional view of a portion of the workpiece 100 at an intermediate stage after partially forming a plurality of interconnects 140. The workpiece 100 can include a substrate 110 and a plurality of microelectronic dies 120 formed in and/or on the substrate 110. The substrate 110 has a first side 112 and a second side 114 opposite the first side 112. The substrate 110 is generally a semiconductor wafer, and the dies 120 are arranged in a die pattern on the wafer. The individual dies 120 include integrated circuitry 122 (shown schematically) and a plurality of terminals 124 (e.g., bond-pads) electrically coupled to the integrated circuitry 122. The terminals 124 shown in FIG. 1A are external features at the first side 112 of the substrate 110. In other embodiments, however, the terminals 124 can be internal features that are embedded at an intermediate depth within the substrate 110. Moreover, in additional embodiments, the dies 120 can have different features to perform different functions. For example, the individual dies may further include an image sensor (e.g., CMOS image sensor or CCD image sensor) for capturing pictures or other images in the visible spectrum, or detecting radiation in other spectrums (e.g., IR or UV ranges).

In previous processing steps, a first dielectric layer 130 was applied to the first side 112 of the substrate 110, and the interconnects 140 were partially formed in the workpiece 100. The first dielectric layer 130 can be a polyimide material or other suitable nonconductive materials. For example, the first dielectric layer 130 can be parylene, a low temperature chemical vapor deposition (low temperature CVD) material such as silicon nitride (Si₃N₄), silicon oxide (SiO₂), and/or other suitable materials. The foregoing list of dielectric materials is not exhaustive. The conductive interconnects 140 extend from the first dielectric layer 130 to an intermediate depth in the substrate 110. As described in greater detail below with regard to FIG. 1B, the conductive interconnects 140 can include several layers of conductive material that are electrically coupled to corresponding terminals 124. Suitable methods for forming the portion of the interconnects 140 illustrated in FIG. 1A are disclosed in U.S. patent application Ser. No. 10/713,878; U.S. patent application Ser. No. 10/867,352; U.S. patent application Ser. No. 10/879,398; U.S. patent application Ser. No. 11/027,443; U.S. patent application Ser. No. 11/056,211; U.S. patent application Ser. No. 11/169,546; U.S. patent application Ser. No. 11/217,877; and U.S. patent application Ser. No. 11/218,243, which are incorporated herein by reference. After partially forming the interconnects 140, the workpiece 100 can optionally be attached to a support member 190 with an adhesive 192 to provide rigidity to the workpiece 100 during subsequent processing steps.

FIG. 1B is a schematic side cross-sectional view of the area 1B shown in FIG. 1A with the workpiece 100 flipped over. The workpiece 100 includes an interconnect hole 180 extending from the terminal 114 to an intermediate depth in the substrate 110, a second dielectric layer 132 in the interconnect hole 180, and a vent hole 182 extending from the interconnect hole 180 to the second side 114 of the substrate 110. The second dielectric layer 132 electrically insulates components in the substrate 110 from the interconnect 140. The second dielectric layer 132 can be an ALD (atomic layer deposition) aluminum oxide material applied using a suitable deposition process or another suitable low temperature CVD oxide. In another embodiment, the second dielectric layer 132 can include a silane-based and/or an aluminum-based oxide material. In still further embodiments, the second dielectric layer 132 can include other suitable dielectric materials.

The illustrated interconnect 140 is formed in the interconnect hole 180 and has a first end portion 142 at the first dielectric layer 130 and a second end portion 144 at an intermediate depth in the substrate 110. The illustrated interconnect 140 includes a diffusion barrier layer 150 deposited over the second dielectric layer 132 in the hole 180, a seed layer 152 formed over the barrier layer 150 in the hole 180, a conductive layer 154 deposited over the seed layer 152 in the hole 180, and a conductive fill material 152 formed over the conductive layer 154 in the hole 180. The diffusion barrier layer 150 can be a layer of tantalum that is deposited onto the workpiece 100 using physical vapor deposition (PVD) and has a thickness of approximately 150 Angstroms. In other embodiments, the barrier layer 150 may be deposited onto the workpiece 100 using other vapor deposition processes, such as CVD, and/or may have a different thickness. In either case, the barrier layer 150 is not limited to tantalum, but rather may be composed of tungsten or other suitable materials that help contain the conductive fill material 156 in the interconnect hole 180.

The seed layer 152 can be deposited using vapor deposition techniques, such as PVD, CVD, atomic layer deposition, and/or plating. The seed layer 152 can be composed of Cu or other suitable materials. The thickness of the seed layer 152 may be about 2000 Angstroms, but could be more or less depending on the depth and aspect ratio of the hole 180. The conductive layer 154 can be Cu that is deposited onto the seed layer 152 in an electroless plating operation, electroplating operation, or another suitable method. The thickness of the conductive layer 154 can be about 1 micron, however, in other embodiments the conductive layer 154 can have a different thickness and/or include other suitable materials. In additional embodiments, the workpiece 100 may include a second conductive layer (not shown) that is deposited over the conductive layer 154 in the hole 180. The second conductive layer can be Ni or other suitable materials that function as a wetting agent for facilitating deposition of subsequent materials into the hole 180.

The conductive fill material 156 can include Cu, Ni, Co, Ag, Au, SnAgCu solder, AuSn solder, a solder having a different composition, or other suitable materials or alloys of materials having the desired conductivity. The conductive fill material 156 may be deposited into the hole 180 using plating processes, solder wave processes, screen printing processes, reflow processes, vapor deposition processes, or other suitable techniques. In other embodiments, the interconnects may have a different structure. For example, the interconnects may have additional layers in lieu of or in addition to the layers described above.

FIG. 1C is a schematic side cross-sectional view of the portion of the workpiece 100 after thinning the substrate 110 from the second side 114. The substrate 110 can be thinned by grinding, dry etching, chemical etching, chemical polishing, chemical-mechanical polishing, or other suitable processes. The thinning process may also remove a section of the second end portion 114 of the interconnect 140. For example, in one embodiment, the initial thickness of the substrate 110 is approximately 750 microns and the interconnect 140 extends to an intermediate depth of approximately 150 microns in the substrate 110, and the post-thinning thickness T of the substrate 110 is approximately 140 microns. These thicknesses can be different in other embodiments. After thinning the workpiece 100, the illustrated interconnect 140 includes an exposed surface 146 at the second end portion 144.

FIG. 1D is a schematic side cross-sectional view of the portion of the workpiece 100 after selectively removing additional material from the second side 114 of the substrate 110 so that the interconnect 140 projects from the substrate 110. The additional material can be removed via a plasma etch with SF₆ or another suitable etchant that is selective to silicon. Alternatively, the additional material can be removed with other processes. In either case, after thinning the substrate 110, the second end portion 144 of the interconnect 140 projects a first distance D₁ from the second side of the substrate 110. In several embodiments, the first distance D₁ is between approximately 5 and 10 microns, although the first distance D₁ can be less than 5 microns or more than 10 microns in other embodiments. The first distance D₁ is selected based on the subsequent processing and application requirements.

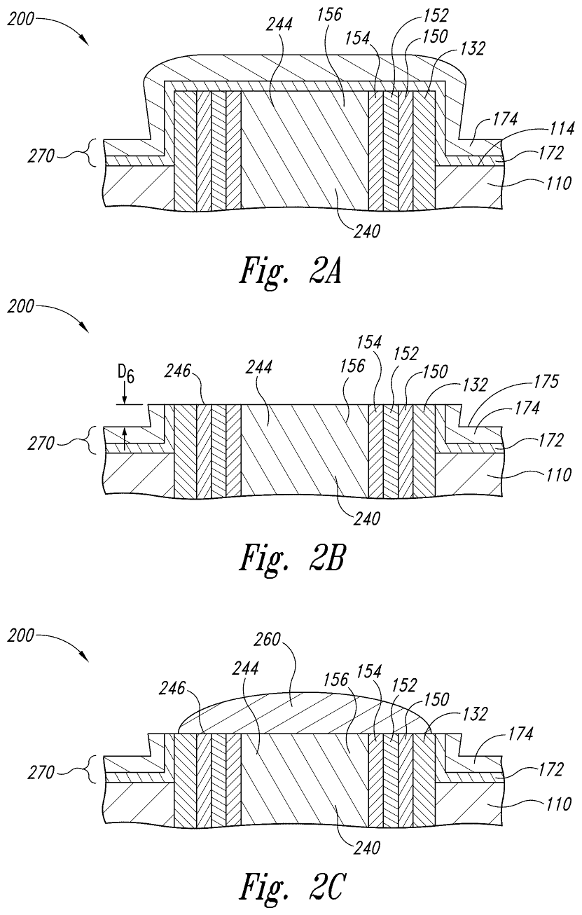

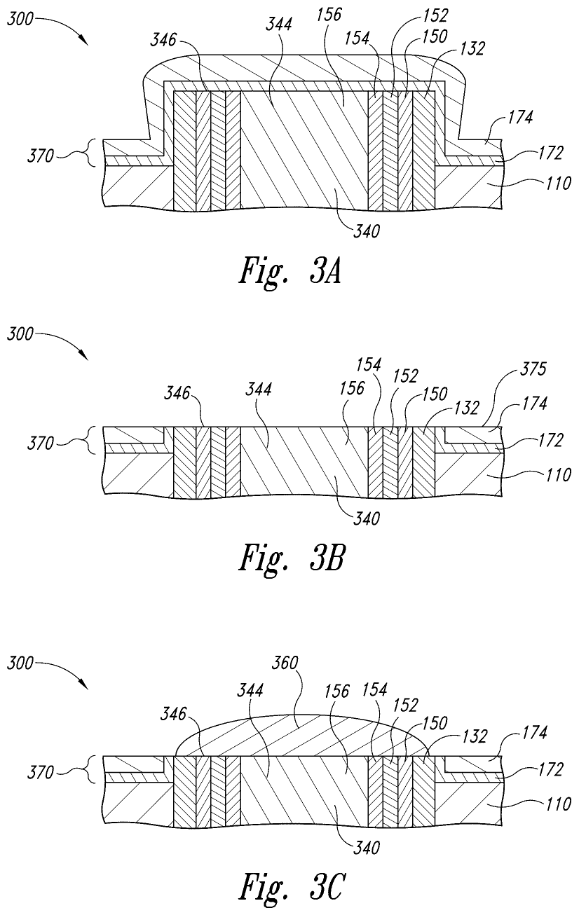

FIG. 1E is a schematic side cross-sectional view of the area 1E shown in FIG. 1D after forming a recess 158 in the second end portion 144 of the interconnect 140. In the illustrated embodiment, the recess 158 is formed by removing a portion of the conductive fill material 156 from the interconnect 140. The conductive fill material 156 can be removed by a wet etch process with an etchant that is selective to the conductive fill material 156 and, consequently, removes the conductive fill material 156 at a faster rate than the seed and/or conductive layers 152 and/or 154. The illustrated recess 158 extends from the surface 146 of the interconnect 140 to a surface 157 of the conductive fill material 156, and has a depth D₂ less than the first distance D₁. The depth D₂ of the recess 158 is selected based on the subsequent processing and application requirements. In other embodiments, such as the embodiments described below with reference to FIGS. 2A-3C, the interconnects may not include a recess in the second end portion 144.

FIG. 1F is a schematic side cross-sectional view of the portion of the workpiece 100 after forming a dielectric structure 170 across the second side 114 of the substrate 110 and the second end portion 144 of the interconnect 140. The illustrated dielectric structure 170 includes a first dielectric layer 172 and a second dielectric layer 174 deposited on the first dielectric layer 172. The first dielectric layer 172 can be parylene HT and have a thickness of approximately 0.5 micron. In other embodiments, other dielectric materials can be used and/or have different thicknesses. The second dielectric layer 174 can be an oxide such as silicon oxide (SiO₂) and/or other suitable materials that are deposited by chemical vapor deposition and/or other suitable processes. In additional embodiments, the dielectric structure 170 can include a different number of layers.

FIG. 1G is a schematic side cross-sectional view of the portion of the workpiece 100 after removing sections of the interconnect 140 and the dielectric structure 170. The sections of the interconnect 140 and the dielectric structure 170 can be removed by grinding, dry etching, chemical etching, chemical polishing, chemical-mechanical polishing, or other suitable processes. In the illustrated embodiment, the workpiece 100 is polished to remove portions of the second dielectric layer 132, the barrier layer 150, the seed layer 152, the conductive layer 154, the first dielectric layer 172, and the second dielectric layer 174. The volume of material removed is selected so that (a) the recess 158 in the interconnect 140 has a desired depth D₃, and (b) the interconnect 140 projects a desired distance D₄ from an exterior surface 175 of the dielectric structure 170. In other embodiments, such as the embodiment described below with reference to FIGS. 3A-3C, the interconnect may not project from the exterior surface 175 of the dielectric structure 170. In either case, the interconnect 140 intersects a plane defined by the dielectric structure 170.

FIG. 1H is a schematic side cross-sectional view of the portion of the workpiece 100 after removing the section of the first dielectric layer 172 from the recess 158 in the interconnect 140. The section of the first dielectric layer 172 can be removed from the recess 158 by a plasma etching process (e.g., O₂ plasma) or another suitable method that selectively removes the first dielectric layer 172 without significantly effecting the dielectric structure 170 formed on the substrate 110.

FIG. 1I is a schematic side cross-sectional view of the portion of the workpiece 100 after forming a conductive member 160 on the second end portion 144 of the interconnect 140. The illustrated conductive member 160 is a cap disposed in the recess 158 and extending over the barrier layer 150, the seed layer 152, and the conductive layer 154. The cap projects a desired distance D₅ from the substrate 110 and forms an external contact for connection to an external device. The conductive member 160 can be electrolessly plated onto the second end portion 144 of the interconnect 140 or formed using other suitable processes. The conductive member 160 can include Ni or other suitable conductive materials. In other embodiments, the interconnect 140 may not include the conductive member 160. For example, the second end portion 144 of the interconnects 140 can be attached directly to an external device, or a conductive coupler (e.g., a solder ball) can be attached directly to the second end portion 144.

One feature of the method illustrated in FIGS. 1A-1I is that the interconnect 140 projects from the substrate 110. As a result, the section of the dielectric structure 170 covering the interconnect 140 can be removed by a simple polishing process without exposing the backside of the substrate 110. The resulting exposed surface 146 on the interconnect 140 may form an external contact to which an external device can be attached. Alternatively, the conductive member 160 can be disposed on the exposed surface 146 and form the external contact. In either case, an advantage of this feature is that the illustrated method does not require expensive and time-consuming photolithography processes to form external contacts on the backside of the workpiece 100.

Another advantage of the method illustrated in FIGS. 1A-1I is that the interconnect 140 can be sized to project a desired distance from the external surface 175 of the dielectric structure 170. The distance can be selected based on the application requirements for the die 110. For example, in applications in which the die 110 is stacked on another die, the distance may be selected to provide a desired gap between the two dies.

### C. Additional Embodiments of Methods for Forming Interconnects in Microfeature Workpieces

FIGS. 2A-2C illustrate stages in a method for forming interconnects in a microfeature workpiece 200 in accordance with another embodiment of the invention. FIG. 2A, for example, is a schematic side cross-sectional view of a portion of the workpiece 200 at an intermediate stage after partially forming an interconnect 240. The illustrated workpiece 200 is generally similar to the workpiece 100 described above with reference to FIGS. 1A-1F. For example, the illustrated workpiece 200 includes a substrate 110, an interconnect 240 extending through and projecting from the substrate 110, and a dielectric structure 270 formed over the substrate 110 and the interconnect 240. The illustrated interconnect 240, however, does not include a recess at the second end portion 244.

FIG. 2B is a schematic side cross-sectional view of the portion of the workpiece 200 after removing sections of the interconnect 240 and the dielectric structure 270. The sections of the interconnect 240 and the dielectric structure 170 can be removed by grinding, dry etching, chemical etching, chemical polishing, chemical-mechanical polishing, or other suitable processes. The volume of the material removed is selected so that the interconnect 240 projects a desired distance D₆ from an exterior surface 275 of the dielectric structure 270. The illustrated interconnect 240 includes a generally planar exposed surface 246 extending across the barrier layer 150, the seed layer 152, the conductive layer 154, and the conductive fill material 156.

FIG. 2C is a schematic side cross-sectional view of the portion of the workpiece 200 after forming a conductive member 260 on the generally planar exposed surface 246 of the interconnect 240. The conductive member 260 forms part of the electrically conductive interconnect 240 and, accordingly, is electrically coupled to the terminal 114 (FIG. 1B).

FIGS. 3A-3C illustrate stages in a method for forming interconnects in a microfeature workpiece 300 in accordance with another embodiment of the invention. FIG. 3A, for example, is a schematic side cross-sectional view of a portion of the workpiece 300 at an intermediate stage after partially forming an interconnect 340. The illustrated workpiece 300 is generally similar to the workpiece 200 described above with reference to FIG. 2A. For example, the illustrated workpiece 300 includes a substrate 110, an interconnect 340 extending through and projecting from the substrate 110, and a dielectric structure 370 formed over the substrate 110 and the interconnect 340.

FIG. 3B is a schematic side cross-sectional view of the portion of the workpiece 300 after removing sections of the interconnect 340 and the dielectric structure 370. The sections of the interconnect 340 and the dielectric structure 370 are removed to form a generally planar surface across the workpiece 300 such that an exposed surface 346 of the interconnect 340 is generally coplanar with an exterior surface 375 of the dielectric structure 370.

FIG. 3C is a schematic side cross-sectional view of the workpiece 300 after forming a conductive member 360 on the exposed surface 346 of the interconnect 340. The conductive member 360 forms part of the electrically conductive interconnect 340 and, accordingly, is electrically coupled to the terminal 114 (FIG. 1B).

From the foregoing, it will be appreciated that specific embodiments of the invention have been described herein for purposes of illustration, but that various modifications may be made without deviating from the spirit and scope of the invention. For example, many of the elements of one embodiment can be combined with other embodiments in addition to or in lieu of the elements of the other embodiments. Accordingly, the invention is not limited except as by the appended claims.

We claim:

1. An integrated circuit structure, comprising:
a substrate having a first side and a second side, wherein the second side is formed by thinning the substrate;
at least one dielectric layer disposed on the second side of the substrate;
a through hole extending through the substrate and through the at least one dielectric layer;
a barrier layer formed in the through hole;
a conductive fill material formed in the through hole and separated from the substrate and the at least one dielectric layer by the barrier layer, wherein an upper surface of the conductive fill material is coplanar with an upper surface of the at least one dielectric layer; and
at least one conductive member disposed over the conductive fill material, wherein the at least one conductive member fully covers the conductive fill material and partially overlaps the at least one dielectric layer.

2. The integrated circuit structure of claim 1, further comprising:
a solder connector disposed on the at least one conductive member.

3. The integrated circuit structure of claim 1, wherein the conductive fill material tapers towards the at least one conductive member.

4. The integrated circuit structure of claim 1, further comprising a metal seed layer disposed between the at least one conductive member and the conductive fill material.

5. The integrated circuit structure of claim 1, wherein the at least one conductive member comprises nickel (Ni).

6. The integrated circuit structure of claim 1, wherein the conductive fill material comprises one or more of Cu, Ni, Co, Ag, Au, SnAgCu, and AuSn.

7. The integrated circuit structure of claim 1, wherein the at least one dielectric layer comprises silicon nitride, silicon oxide, polyimide, parylene, or a combination thereof.

8. A semiconductor device, comprising:
a silicon substrate having a first side and a second side, wherein the second side includes mechanical deformations formed by polishing or etching;
a silicon nitride layer disposed on the second side of the substrate;
a through hole extending through the silicon substrate and through the silicon nitride layer;
a conductive fill material formed in the through hole and separated from the silicon substrate and the silicon nitride layer by a barrier layer in the through hole, wherein an upper surface of the conductive fill material is coplanar with an upper surface of the silicon nitride layer; and
at least one conductive member disposed over the conductive fill material, wherein the at least one conductive member fully covers the conductive fill material, and wherein the at least one conductive member partially overlaps the at least one dielectric layer.

9. The semiconductor device of claim 8, further comprising:
a solder connector disposed on the at least one conductive member.

10. The semiconductor device of claim 8, wherein the through hole tapers towards the at least one conductive member.

11. The semiconductor device of claim 8, further comprising a metal seed layer disposed between the at least one conductive member and the conductive fill material.

12. The semiconductor device of claim 8, wherein the at least one conductive member comprises nickel (Ni).

13. The semiconductor device of claim 8, wherein the conductive fill material comprises one or more of Cu, Ni, Co, Ag, Au, SnAgCu, and AuSn.

14. An integrated circuit structure, comprising:
a substrate having a first side and a second side, wherein the second side is formed by thinning the substrate;
a silicon nitride layer disposed on the second side of the substrate;
a tapered opening extending through the substrate and through the silicon nitride layer, wherein the opening tapers towards the silicon nitride layer;
a conductive fill material formed in the opening and separated from the substrate and the silicon nitride layer by a barrier layer, wherein an upper surface of the conductive fill material is coplanar with an upper surface of the silicon nitride layer; and
at least one conductive member disposed over the conductive fill material, wherein the at least one conductive member fully covers an end surface of the conductive fill material and partially overlaps the silicon nitride layer.

15. The integrated circuit structure of claim 14, further comprising:
a solder connector disposed on the at least one conductive member.

16. The integrated circuit structure of claim 14, further comprising a metal seed layer disposed between the at least one conductive member and the conductive fill material.

17. The integrated circuit structure of claim 14, wherein the at least one conductive member comprises nickel (Ni).

18. The integrated circuit structure of claim 14, wherein the conductive fill material comprises one or more of Cu, Ni, Co, Ag, Au, SnAgCu, and AuSn.
